(19) United States
(12) Patent Application Publication
(10) Pub. No.: US 2016/0178978 A1
(43) Pub. Date: Jun. 23, 2016

(54) FFS Mode Array Substrate and LCD Panel

(71) Applicant: SHENZHEN CHINA STAR OPTOELECTRONICS TECHNOLOGY CO., LTD., Shenzhen, Guangdong (CN)

(72) Inventor: Sikun Hao, Shenzhen, Guangdong (CN)

(21) Appl. No.: 14/418,035

(22) PCT Filed: Dec. 30, 2014
(86) PCT No.: PCT/CN2014/095512

§ 371 Date: Jan. 28, 2015

(30) Foreign Application Priority Data
Dec. 22, 2014 (CN) 201410810687.5

(51) Int. Cl. G02F 1/1343; G02F 1/1337; G02F 1/1362; G02F 1/1333; H01L 27/12; G02F 1/1368

(52) U.S. Cl. CPC G02F 1/134363; H01L 27/124; H01L 27/1248; G02F 1/1368; G02F 1/136286; G02F 1/133345; G02F 1/13439; G02F 1/136227; G02F 1/133707; G02F 2001/134372

(57) ABSTRACT

An FFS mode array substrate and an LCD panel having the FFS array substrate are provided. The FFS array substrate includes a base substrate, a first metal layer, a first insulation layer, a second metal layer, a second insulation layer, a common electrode layer, a third insulation layer, and a transparent electrode layer; wherein the common electrode layer includes a common electrode line and a transparent common electrode, and a resistivity of the common electrode line is lower than a resistivity of the transparent common electrodes. This can assure stability of the electric potentials of the common electrodes, and thereby the display performance of an LCD display device having the FFS array substrate is improved.

### BACKGROUND OF THE INVENTION

1. Field of the Invention

The present invention relates to liquid crystal display (LCD) technology, and more particularly to a fringe field switching (FFS) mode array substrate and an LCD panel.

2. Description of Prior Art

LCD devices are used extensively as flat display devices on a variety of electronic devices such as, for example, mobile phones, personal digital assistants (PDA), digital cameras, and personal computers, to provide color display screens with high resolution. FFS mode LCD devices are popular with most customers.

The FFS mode LCD device which is now widely used includes an upper substrate, a lower substrate, and a liquid crystal layer interposed between the substrates. Typically, a planar common electrode and pixel electrodes, each of which has a configuration of slits, are disposed on the lower substrate of the FFS mode LCD device in order to attain a better display performance.

Simultaneously, each pixel has a structure including multiple regions with slits that have different extension directions to form multiple display domains in order to avoid a problem concerning an LCD device with too narrow a viewing angle. Due to different pre-deflections of liquid crystal molecules located in different display domains, light transmitted from a liquid crystal layer can be enlarged so that a wide viewing angle display for an LCD display device can be carried out.

Likewise, the common electrode disposed on the lower substrate of the conventional FFS mode LCD device is typically a transparent electrode in order to enlarge the aperture ratio of the LCD display device. However, the transparent electrode has larger impedance so that the electric potential of the common electrode in the conventional FFS mode LCD device is unstable when there is larger current passing through the common electrode.

In light of the foregoing, it is desirable to provide an FFS mode array substrate and an FFS mode LCD panel that is able to solve the existing technical problems.

### SUMMARY OF THE INVENTION

The object of the present invention is to provide an FFS mode array substrate with stable electric potentials of common electrodes therein and an LCD panel having the FFS array substrate in order to solve the existing technical problems, in which the electric potentials of the common electrodes in the conventional FFS mode LCD device are unstable.

To solve the foregoing problems, a couple of technical solutions are provided. According to one aspect of the present invention, an FFS array substrate comprises: a base substrate; a first metal layer disposed on the base substrate to form a scan line and a gate electrode of a thin film transistor; a first insulation layer disposed on the first metal layer to electrically insulate the first metal layer from a second metal layer; a second metal layer disposed on the first insulation layer to form a data line, a source electrode of the thin film transistor, and a drain electrode of the thin film transistor; a second insulation layer disposed on the second metal layer to electrically insulate the second metal layer from a common electrode layer; a common electrode layer including a common electrode line disposed on the second insulation layer and a transparent common electrode disposed on the common electrode line and the second insulation layer, wherein a resistivity of the common electrode line is lower than a resistivity of the transparent common electrode; a third insulation layer disposed on the common electrode layer to electrically insulate a common electrode layer from a transparent electrode layer; and a transparent electrode layer disposed on the third insulation layer to form a transparent pixel electrode, which is electrically connected with the drain electrode of the thin film transistor by passing through the third insulation layer, the common electrode layer, and a first through-hole of the second insulation layer.

According to one aspect of the present invention, a slit structure is arranged on a surface of the transparent pixel electrode.

According to one aspect of the present invention, the FFS array substrate contains multiple display domains.

According to one aspect of the present invention, extension directions of slits of the slit structure are distinct for each display domain.

According to one aspect of the present invention, the common electrode line is arranged on a junction between two adjacent display domains in the FFS array substrate.

According to one aspect of the present invention, the second metal layer includes a common line used for transferring a common signal, and the common electrode layer is electrically connected to the common line of the second metal layer by passing through a second through-hole of the second insulation layer.

According to one aspect of the present invention, the common electrode layer includes a transparent common electrode disposed on the second insulation layer and a common electrode line disposed on the transparent common electrode, and wherein a resistivity of the common electrode line is lower than a resistivity of the transparent common electrode.

According to another aspect of the present invention, an FFS array substrate comprises: a base substrate; a first metal layer disposed on the base substrate to form a scan line and a gate electrode of a thin film transistor; a first insulation layer disposed on the first metal layer to electrically insulate the first metal layer from a second metal layer as well as electrically insulate the first metal layer from a common electrode layer; and a second metal layer disposed on the first insulation layer to form a data line, a source electrode of a thin film transistor, and a drain electrode of a thin film transistor; a common electrode layer including a common electrode line disposed on the first insulation layer and a transparent common electrode disposed on the common electrode line and the first insulation layer, wherein a resistivity of the common electrode line is lower than a resistivity of the transparent common electrode; a second insulation layer disposed on the second metal layer and the common electrode layer to electrically insulate the second metal layer from the transparent electrode layer as well as electrically insulate the common electrode layer from a transparent electrode layer; and a transparent electrode layer disposed on the second insulation layer to form a transparent pixel electrode, which are electrically connected with the drain electrode of the thin film transistor by passing through a first through-hole of the second insulation layer.

According to another aspect of the present invention, a slit structure is arranged on a surface of the transparent pixel electrode.

According to another aspect of the present invention, the FFS array substrate contains multiple display domains.

According to another aspect of the present invention, extension directions of slits of the slit structure are distinct for each display domain.

According to another aspect of the present invention, the common electrode line is arranged on a junction between two adjacent display domains in the FFS array substrate.

According to one aspect of the present invention, the second metal layer includes a common line used for transferring a common signal, and the common electrode layer is electrically connected to the common line of the second metal layer by passing through a second through-hole of the second insulation layer.

According to one embodiment of the present invention, the present invention also provides a FFS mode LCD display panel including an upper substrate, an FFS array substrate, and a liquid crystal layer interposed between the upper substrate and the FFS array substrate, and the FFS array substrate comprises: a base substrate; a first metal layer disposed on the base substrate to form a scan line and a gate electrode of a thin film transistor; a first insulation layer disposed on the first metal layer to electrically insulate the first metal layer from a second metal layer; a second metal layer disposed on the first insulation layer to form a data line, a source electrode of the thin film transistor, and a drain electrode of the thin film transistor; a second insulation layer disposed on the second metal layer to electrically insulate the second metal layer from a common electrode layer; a common electrode layer including a common electrode line disposed on the second insulation layer and a transparent common electrode disposed on the common electrode line and the second insulation layer, wherein a resistivity of the common electrode line is lower than a resistivity of the transparent common electrode; a third insulation layer disposed on the common electrode layer to electrically insulate a common electrode layer from a transparent electrode layer; and a transparent electrode layer disposed on the third insulation layer to form a transparent pixel electrode, which is electrically connected with the drain electrode of the thin film transistor by passing through the third insulation layer, the common electrode layer, and a first through-hole of the second insulation layer.

According to one embodiment of the present invention, a slit structure is arranged on a surface of the transparent pixel electrode.

According to one embodiment of the present invention, the FFS array substrate contains multiple display domains.

According to one embodiment of the present invention, extension directions of slits of the slit structure are distinct for each display domain.

According to one embodiment of the present invention, the common electrode line is arranged on a junction between two adjacent display domains in the FFS array substrate.

According to one embodiment of the present invention, the second metal layer includes a common line used for transferring a common signal, and the common electrode layer is electrically connected to the common line of the second metal layer by passing through a second through-hole of the second insulation layer.

According to one aspect of the present invention, the common electrode layer includes a transparent common electrode disposed on the second insulation layer and a common electrode line disposed on the transparent common electrode, and wherein a resistivity of the common electrode line is lower than a resistivity of the transparent common electrode.

Compared with the prior art, the FFS array substrate and the LCD display panel having the array substrate in accordance with the present invention can assure stability of the electric potentials of the common electrodes by means of the disposition of the common electrode layer that includes a common electrode line and the transparent common electrodes. Thus, the display performance of the LCD display device having the FFS array substrate of the present invention is improved. Therefore, the existing technical problem of unstable electric potentials on the common electrodes of the conventional LCD can be solved.

The foregoing, as well as additional objects, features, and advantages of the invention will be more apparent from the following detailed description, which proceeds with reference to the accompanying drawings.

### BRIEF DESCRIPTION OF THE DRAWINGS

FIG. 1A is a top view of a schematic diagram of an FFS array substrate in accordance with a first preferred embodiment.

FIG. 1B is a cross-sectional view of a schematic diagram along the cross-sectional line A-A′ shown in FIG. 1A.

FIG. 2A is a top view of a schematic diagram of an FFS array substrate in accordance with a second preferred embodiment.

FIG. 2B is a cross-sectional view of a schematic diagram along the cross-sectional line B-B′ shown in FIG. 2A.

FIG. 3A is a top view of schematic diagram of an FFS array substrate in accordance with a three preferred embodiment.

FIG. 3B is a cross-sectional view of a schematic diagram along the cross-sectional line C-C′ shown in FIG. 3A.

FIG. 4A is a top view of a schematic diagram of an FFS array substrate in accordance with a fourth preferred embodiment.

FIG. 4B is a cross-sectional view of a schematic diagram along the cross-sectional line D-D′ shown in FIG. 4A.

FIG. 5A is a top view of a schematic diagram of an FFS array substrate in accordance with a fifth preferred embodiment.

FIG. 5B is a cross-sectional view of a schematic diagram along the cross-sectional line E-E′ shown in FIG. 5A.

FIG. 6A is a top view of a schematic diagram of an FFS array substrate in accordance with a sixth preferred embodiment.

FIG. 6B is a cross-sectional view of a schematic diagram along the cross-sectional line F-F′ shown in FIG. 6A.

FIG. 7 is a top view of a schematic diagram of an FFS array substrate in accordance with a seventh preferred embodiment.

FIG. 8 is a top view of a schematic diagram of an FFS array substrate in accordance with an eighth preferred embodiment.

### DETAILED DESCRIPTION OF THE INVENTION

The preferred embodiments of the present invention are illustrated in the accompanying drawings with numbered elements. Spatially relative terms, such as “above”, “beneath”, “upper”, “lower”, “left”, “right”, “inner”, “outer”, and the like may be used herein for ease of understanding the present invention, rather than its restrictions.

Throughout the specification and drawings, identical reference numerals refer to identical or similar parts.

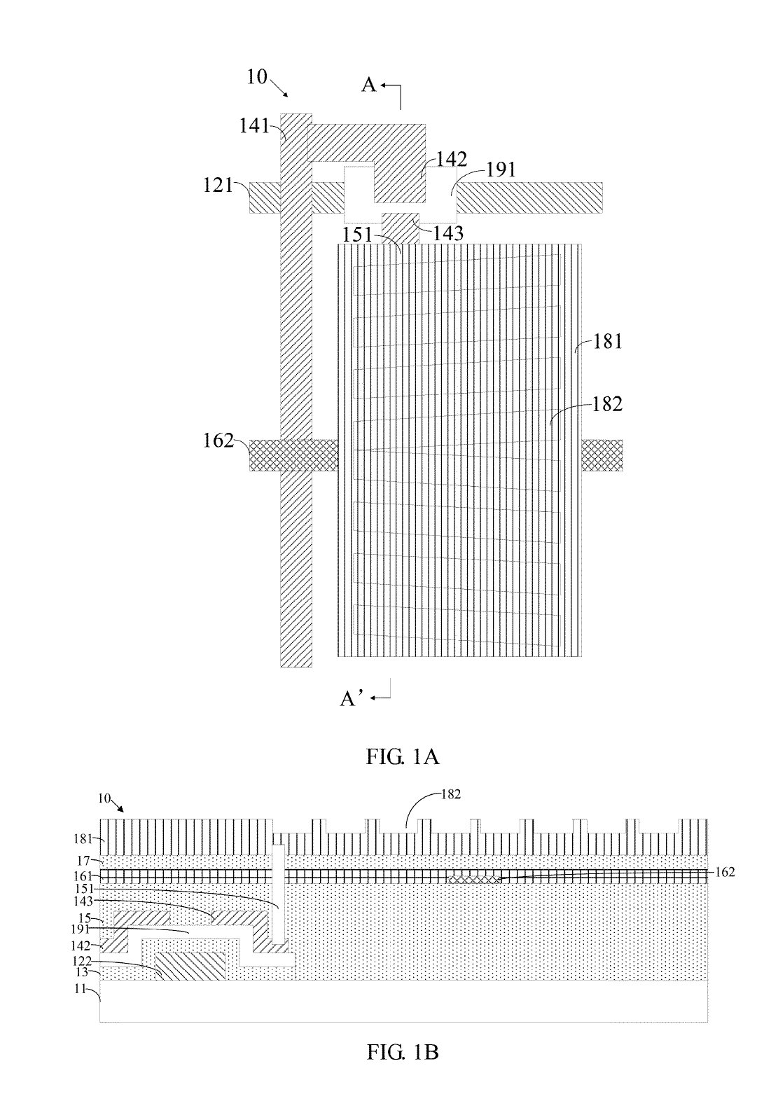

With reference to FIG. 1A and FIG. 1B, an FFS array substrate in accordance with a first preferred embodiment will now be described. FIG. 1A is a top view of a schematic diagram of an FFS array substrate in accordance with the first preferred embodiment, and FIG. 1B is a cross-sectional view of a schematic diagram along the cross-sectional line A-A′ shown in FIG. 1A. In accordance with the first preferred embodiment, the FFS array substrate 10 includes a base substrate 11, a first metal layer, a first insulation layer 13, a second metal layer, a second insulation layer 15, a common electrode layer, a third insulation layer 17, and a transparent electrode layer.

The first metal layer disposed on the base substrate 11 is used to form a scan line 121 and a gate electrode of a thin film transistor 122. The first insulation layer 13 disposed on the first metal layer is used for electrically insulating the first metal layer from the second metal layer. The second metal layer disposed on the first insulation layer 13 is used to form a data line 141, a source electrode of the thin film transistors 142, and a drain electrode of the thin film transistor 143. The second insulation layer 15 disposed on the second metal layer is used for electrically insulating the second metal layer from a common electrode layer. The common electrode layer includes a common electrode line 162 disposed on the second insulation layer 15, and a transparent common electrode 161 disposed on the common electrode line 162 and a second insulation layer 15, wherein the resistivity of the common electrode line 162 is lower than the resistivity of the transparent common electrodes 161. The third insulation layer 17 disposed on the common electrode layer is used for electrically insulating a transparent electrode layer from the common electrode layer. The transparent electrode layer disposed on the third insulation layer 17 is used to form a transparent pixel electrode 181. The transparent pixel electrode 181 is electrically connected with the drain electrode of the thin film transistor 143 by passing through the third insulation layer 17, the common electrode layer, and the first through-hole 151 of the second insulation layer 15. Additionally, the FFS array substrate 10 also includes a semiconductor layer used for forming channels 191.

The FFS array substrate 10 contains multiple display domains, and therein of a slit structure 182 is arranged on a surface of the transparent pixel electrode 181 and extension directions of slits of the slit structure 182 are distinct for each display domain of the FFS array substrate 10. The common electrode line 162 is arranged on a junction between two adjacent display domains.

When the FFS array substrate 10 is in operation, the transparent pixel electrodes 181 on the transparent electrode layer receive data signals on the data line through the first through-hole 151, the drain electrode of the thin film transistor 143, and the source electrodes of thin film transistors 142. The transparent common electrodes 161 included in the common electrode layer receive common signals via the common electrode line 162. Under actions of the data signals and the common signals, liquid crystal molecules in a liquid crystal layer of the LCD display device are deflected, and corresponding images are displayed on the LCD display device.

Because the common electrode line 162 is made of a metal line with low resistivity, the entire resistivity of the common electrode layer is able to be reduced such that the electrical potentials of the common electrodes are more stable and uniform.

Due to a junction between two adjacent display domains in an array substrate being a poor display area, the arrangement of making the opaque common electrode line 162 dispose on the junctions can avoid a substantially significant impact to the aperture ratio of the LCD display panel. Consequently, the impedances of the common electrodes are decreased under such an arrangement which can cause less impact to the aperture ratio of the LCD display device.

Furthermore, the common electrode line 162 is connected to every pixel in the LCD display device, and the common electrode line 162 can be also used to transfer a touch signal when there is equipped with a touch device on the surface of the LCD display device.

The FFS array substrate in accordance with the first preferred embodiment can assure stability of the electric potentials of the common electrodes by means of the disposition of the common electrode layer that includes a common electrode line and the transparent common electrodes. Therefore, the display performance of the LCD display device having the FFS array substrate of the present invention is improved.

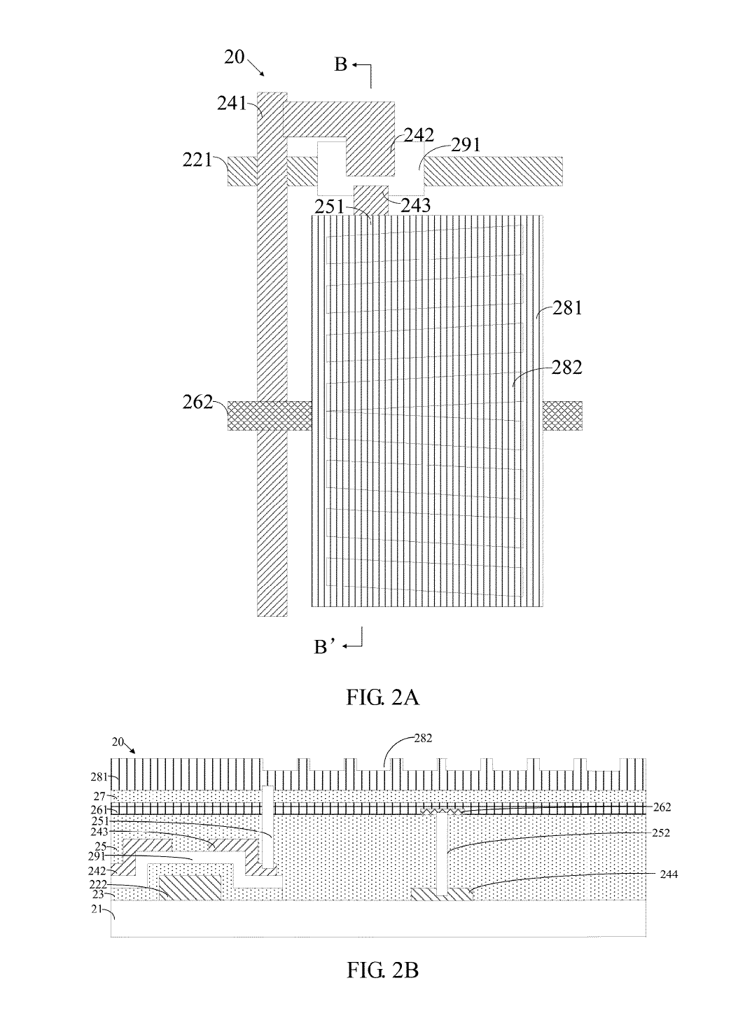

With reference to FIG. 2A and FIG. 2B, an FFS array substrate in accordance with a second preferred embodiment will now be described. FIG. 2A is a top view of a schematic diagram of an FFS array substrate in accordance with the second preferred embodiment, and FIG. 2B is a cross-sectional view of a schematic diagram along the cross-sectional line B-B′ shown in FIG. 2A. In accordance with the second preferred embodiment, the FFS array substrate 20 includes a base substrate 21, a first metal layer, a first insulation layer 23, a second metal layer, a second insulation layer 25, a common electrode layer, a third insulation layer 27, and a transparent electrode layer.

The second metal layer disposed on the base substrate 21 is used to form a scan line 221 and a gate electrode of a thin film transistor 222. The first insulation layer 23 disposed on the first metal layer is used for electrically insulating the first metal layer from the second metal layer. The second metal layer disposed on the first insulation layer 23 is used to form a data line 241, a source electrode of a thin film transistor 242, and a drain electrode of a thin film transistor 243. The second insulation layer 25 disposed on the second metal layer is used for electrically insulating the second metal layer from a common electrode layer. The common electrode layer includes a common electrode line 262 disposed on the second insulation layer 25, and a transparent common electrode 261 disposed on the common electrode line 262 and a third insulation layer 27, wherein a resistivity of the common electrode line 262 is lower than a resistivity of the transparent common electrodes 261. The third insulation layer 27 disposed on the common electrode layer is used for electrically insulating a transparent electrode layer from the common electrode layer. The transparent electrode layer disposed on the third insulation layer 27 is used to form a transparent pixel electrode 281. The transparent pixel electrode 281 is electrically connected with the drain electrode of the thin film transistor 243 by passing through the third insulation layer 27, the common electrode layer, and the first through-hole 251 of the second insulation layer 25. Additionally, the FFS array substrate 20 also includes a semiconductor layer used for forming channels 291.

The FFS array substrate 20 contains multiple display domains, and therein a slit structure 282 is arranged on a surface of a transparent pixel electrode 281 and extension directions of slits of the slit structure 282 are distinct for each display domain of the FFS array substrate 20. The common electrode line 262 is arranged on a junction between two adjacent display domains.

On basis of the first preferred embodiment, the FFS array substrate 20 in accordance with the second preferred embodiment also includes a common line 244 disposed on the second metal layer, and the common line 244 is used for transferring a common signal. The common electrode layer is electrically connected to the common line 244 disposed on the first metal layer by passing through a second through-hole 252 of the second insulation layer 25. Alternatively, the common line 244 may be also disposed on the second metal layer.

When the FFS array substrate 20 is in operation, the transparent pixel electrodes 281 on the transparent electrode layer receive data signals on the data line through the first through-hole 251, the drain electrode of the thin film transistor 243 and the source electrode of the thin film transistor 242. The transparent common electrode 261 on the common electrode layer receives a common signal through the common electrode line 262 on the common electrode layer, the second through-hole 252, and a common line 244 on the second metal layer. Under actions of the data signals and the common signals, liquid crystal molecules in a liquid crystal layer of the LCD display device are deflected, and corresponding images are displayed on the LCD display device.

The FFS array substrate of the second preferred embodiment transfers the common signal via the common line on the second metal layer such that the common electrode line included in the common electrode layer is not required to be reached all over the entire LCD display device. Accordingly, the arrangement of the common electrodes line creates less impact to the aperture ratio of the LCD display device.

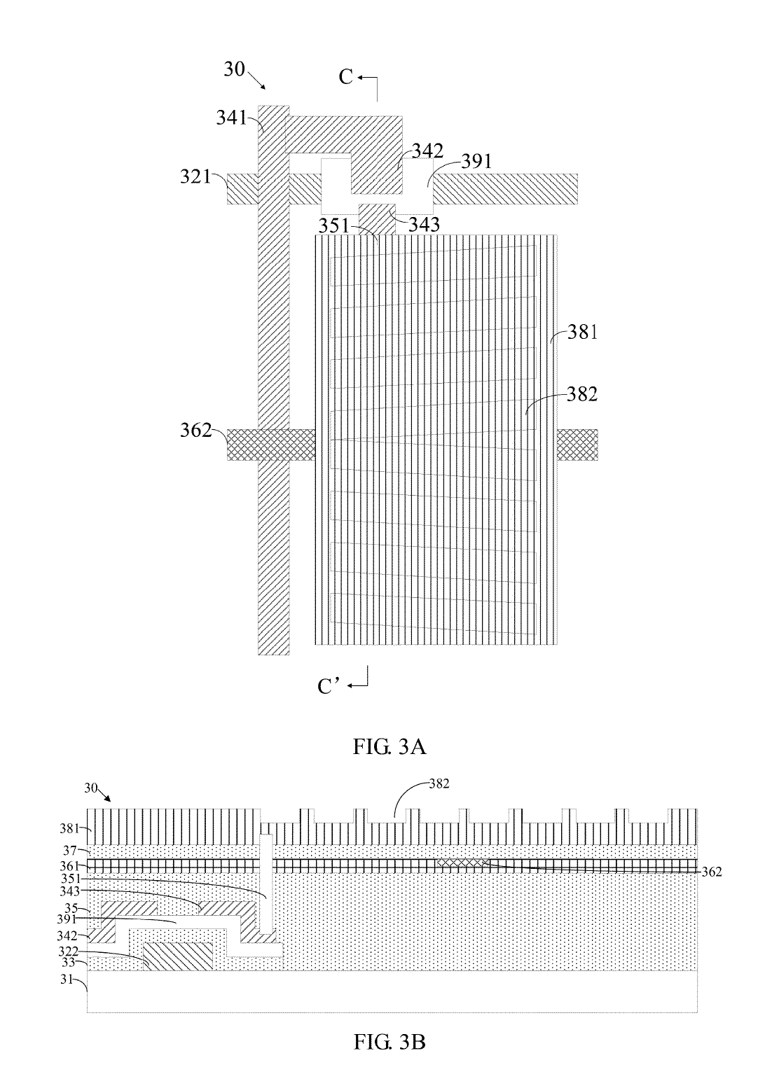

With reference to FIG. 3A and FIG. 3B, an FFS array substrate in accordance with a third preferred embodiment, will now be described. FIG. 3A is a top view of a schematic diagram of an FFS array substrate in accordance with the third preferred embodiment, and FIG. 3B is a cross-sectional view of a schematic diagram along the cross-sectional line C-C′ shown in FIG. 3A. In accordance with the third preferred embodiment, the FFS array substrate 30 includes a base substrate 31, a third metal layer, a third insulation layer 33, a second metal layer, a second insulation layer 35, a common electrode layer, a third insulation layer 37, and a transparent electrode layer.

The first metal layer disposed on the base substrate 31 is used to form a scan line 321 and a gate electrode of a thin film transistor 322. The first insulation layer 33 disposed on the first metal layer is used for electrically insulating the first metal layer from the second metal layer. The second metal layer disposed on the first insulation layer 33 is used to form a data line 341, a source electrode of the thin film transistor 342, and a drain electrode of the thin film transistor 343. The second insulation layer 35 disposed on the second metal layer is used for electrically insulating the second metal layer from a common electrode layer. The common electrode layer includes a transparent common electrode 361 disposed on the second insulation layer 35 and a common electrode line 362 disposed on the transparent common electrodes 361, wherein a resistivity of the common electrode line 362 is lower than a resistivity of the transparent common electrodes 361. The third insulation layer 37 disposed on the common electrode layer is used for electrically insulating a transparent electrode layer from the common electrode layer. The transparent electrode layer disposed on the third insulation layer 37 is used to form a transparent pixel electrode 381. The transparent pixel electrode 381 is electrically connected with the drain electrode of the thin film transistor 343 by passing through the third insulation layer 37, the common electrode layer, and the first through-hole 351 of the second insulation layer 35. Additionally, the FFS array substrate 30 also includes a semiconductor layer used for forming channels 391.

The FFS array substrate 30 contains multiple display domains, and therein a slit structure 382 is arranged on a surface of the transparent pixel electrode 381 and extension directions of slits of the slit structure 382 are distinct for each display domain of the FFS array substrate 30. The common electrode line 362 is arranged on a junction between two adjacent display domains.

The distinction between the first preferred embodiment and the third preferred embodiment is in regards to the disposition of the common electrode line 362, which is disposed on the transparent common electrodes 361 in the third preferred embodiment. The specific operations of the FFS array substrate 30 are similar to the FFS array substrate described in the first embodiment; please refer to the relevant detailed description in the aforementioned preferred embodiments.

The FFS array substrate in accordance with the third preferred embodiment can assure stability of the electric potentials of the common electrodes by means of the disposition of the common electrode layer that includes a common electrode line and the transparent common electrodes. Therefore, the display performance of the LCD display device having the FFS array substrate of the present invention is improved.

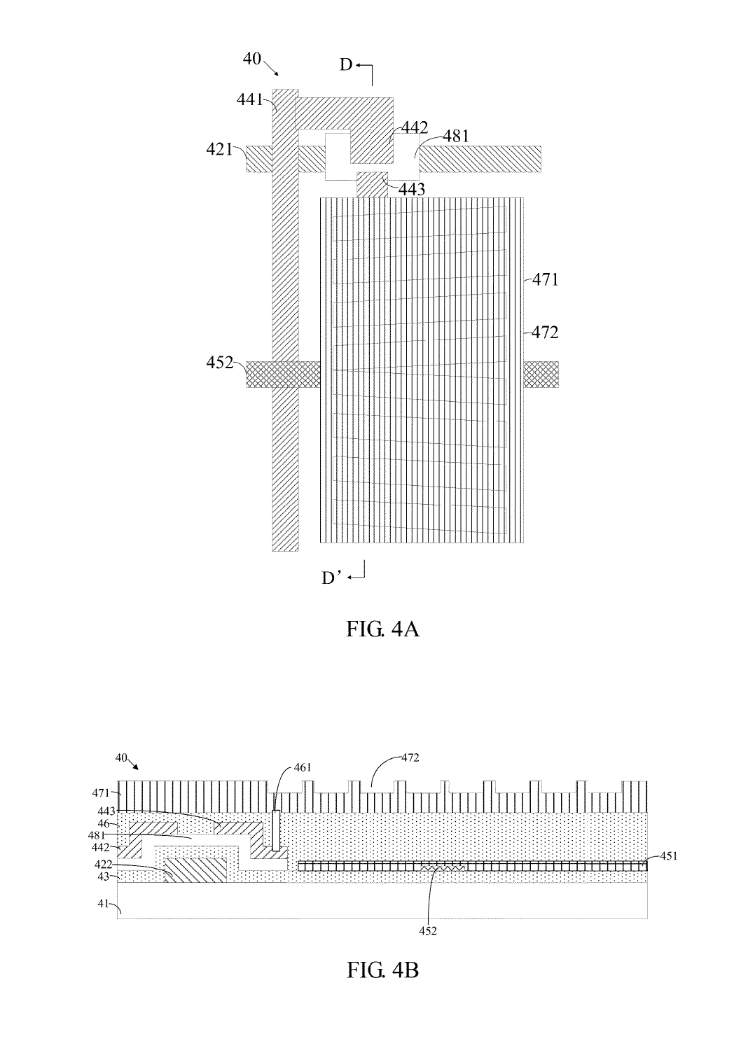

With reference to FIG. 4A and FIG. 4B, an FFS array substrate in accordance with a fourth preferred embodiment will now be described. FIG. 4A is a top view of a schematic diagram of an FFS array substrate in accordance with the fourth preferred embodiment, and FIG. 4B is a cross-sectional view of a schematic diagram along the cross-sectional line D-D′ shown in FIG. 4A. In accordance with the fourth preferred embodiment, the FFS array substrate 40 includes a base substrate 41, a first metal layer, a first insulation layer 53, a second metal layer, a common electrode layer, a second insulation layer 46, and a transparent electrode layer.

The first metal layer disposed on the base substrate 41 is used to form a scan line 421 and a gate electrode of a thin film transistor 422. The first insulation layer 43 disposed on the first metal layer is used for electrically insulating the first metal layer from the second metal layer and electrically insulating the first metal layer from a common electrode layer. The second metal layer disposed on the first insulation layer 43 is used to form a data line 441, a source electrode of the thin film transistor 442 and a drain electrode of the thin film transistor 443. The common electrode layer includes a common electrode line 452 disposed on the first insulation layer 43, and a transparent common electrode 451 disposed on the common electrode line 452 and a first insulation layer 43, wherein a resistivity of the common electrode line 452 is lower than a resistivity of the transparent common electrodes 451. The second insulation layer 46, disposed on the second metal layer and a transparent electrode layer is used for electrically insulating the common electrode layer from the transparent electrode layer and electrically insulating the second metal layer from the transparent electrode layer. The transparent electrode layer disposed on the second insulation layer 46 is used to form a transparent pixel electrode 471. The transparent pixel electrode 471 is electrically connected with the drain electrode of the thin film transistor 443 by passing through the first through-hole 461 of the second insulation layer 46. Additionally, the FFS array substrate 40 also includes a semiconductor layer used for forming channels 481.

The FFS array substrate 40 contains multiple display domains, and therein a slit structure 482 is arranged on a surface of the transparent pixel electrode 471 and extension directions of slits of the slit structure 482 are distinct for each display domain of the FFS array substrate 40. The common electrode line 452 is arranged on a junction between two adjacent display domains.

When the FFS array substrate 40 is in operation, the transparent pixel electrodes 471 on the transparent electrode layer receive data signals on the data line through the first through-hole 461, the drain electrode of the thin film transistor 443 and the source electrode of the thin film transistor 442. The transparent common electrodes 451 included in the common electrode layer receive common signals via the common electrode line 452. Under actions of the data signals and the common signals, liquid crystal molecules in a liquid crystal layer of the LCD display device are deflected, and corresponding images are displayed on the LCD display device.

Because the common electrode line 452 is made of a metal line with low resistivity, the entire resistivity of the common electrode layer is able to be reduced such that the electrical potentials of the common electrodes are more stable and uniform.

Due to a junction between two adjacent display domains in an array substrate being a poor display area, the arrangement disposing the opaque common electrode line 452 on the junctions can avoid a substantially significant impact to the aperture ratio of the LCD display panel. Consequently, the impedances of the common electrodes are decreased under such arrangement which can cause less impact to the aperture ratio of the LCD display device.

Furthermore, the common electrode line 452 is connected to every pixel in the LCD display device, and the common electrode line 452 can be also used to transfer a touch signal when there is equipped with a touch device on the surface of the LCD display device.

The FFS array substrate in accordance with the fourth preferred embodiment can assure stability of the electric potentials of the common electrodes by means of the disposition of the common electrode layer that includes a common electrode line and the transparent common electrodes. Therefore, the display performance of the LCD display device having the FFS array substrate of the present invention is improved.

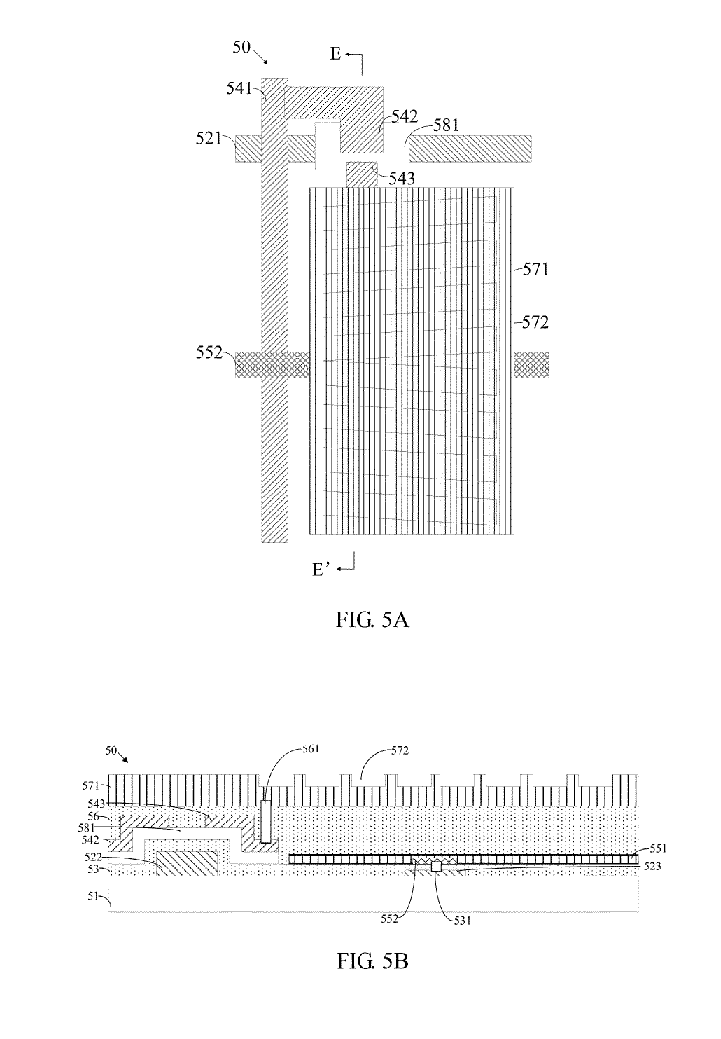

With reference to FIG. 5A and FIG. 5B, an FFS array substrate in accordance with a fifth preferred embodiment will now be described. FIG. 5A is a top view of a schematic diagram of an FFS array substrate in accordance with the fifth preferred embodiment, and FIG. 5B is a cross-sectional view of a schematic diagram along the cross-sectional line E-E′ shown in FIG. 5A. In accordance with the fifth preferred embodiment, the FFS array substrate 50 includes a base substrate 51, a first metal layer, a first insulation layer 53, a second metal layer, a common electrode layer, a second insulation layer 46, and a transparent electrode layer.

The first metal layer disposed on the base substrate 51 is used to form a scan line 521 and a gate electrode of a thin film transistor 522. The first insulation layer 53 disposed on the first metal layer is used for electrically insulating the first metal layer from the second metal layer. The second metal layer disposed on the first insulation layer 53 is used to form a data line 541, a source electrode of the thin film transistor 542, and a drain electrode of the thin film transistor 543. The common electrode layer includes a common electrode line 552 disposed on the first insulation layer 53 and a transparent common electrode 551 disposed on the common electrode line 552 and a first insulation layer 53, wherein a resistivity of the common electrode line 552 is lower than a resistivity of the transparent common electrodes 551. The second insulation layer 56 disposed on the second metal layer and a transparent electrode layer is used for electrically insulating the common electrode layer from the transparent electrode layer as well as electrically insulating the second metal layer from the transparent electrode layer. The transparent electrode layer disposed on the second insulation layer 56 is used to form a transparent pixel electrode 571. The transparent pixel electrode 571 is electrically connected with the drain electrode of the thin film transistor 543 by passing through the first through-hole 561 of the second insulation layer 56. Additionally, the FFS array substrate 50 also includes a semiconductor layer used for forming channels 581.

The FFS array substrate 50 contains multiple display domains, and therein a slit structure 582 is arranged on a surface of the transparent pixel electrode 571 and extension directions of slits of the slit structure 582 are distinct for each display domain of the FFS array substrate 50. The common electrode line 552 is arranged on a junction between two adjacent display domains.

On basis of the fourth preferred embodiment, the FFS array substrate 50 in accordance with the fifth preferred embodiment also includes a common line 523 disposed on the first metal layer, and the common line is used for transferring common signals. The common electrode is electrically connected to the common line 523 disposed on the first metal layer by passing through a second through-hole 531 of the first insulation layer 53.

When the FFS array substrate 50 is in operation, the transparent pixel electrodes 571 on the transparent electrode layer receive data signals on the data line through the first through-hole 561, the drain electrode of the thin film transistor 543 and the source electrode of the thin film transistor 542. The transparent common electrode 551 included in the common electrode layer receive common signals via the common electrode line 552, through the second through-hole 531, and via the common line 523 disposed on the first metal layer. Under actions of the data signals and the common signals, liquid crystal molecules in a liquid crystal layer of the LCD display device are deflected, and corresponding images are displayed on the LCD display device.

The FFS array substrate of the fifth preferred embodiment transfers the common signals via the common line on the first metal layer such that the common electrode line included in the common electrode layer is not required to be reached all over the entire LCD display device. Accordingly, the arrangement of the common electrodes line creates less impact to the aperture ratio of the LCD display device.

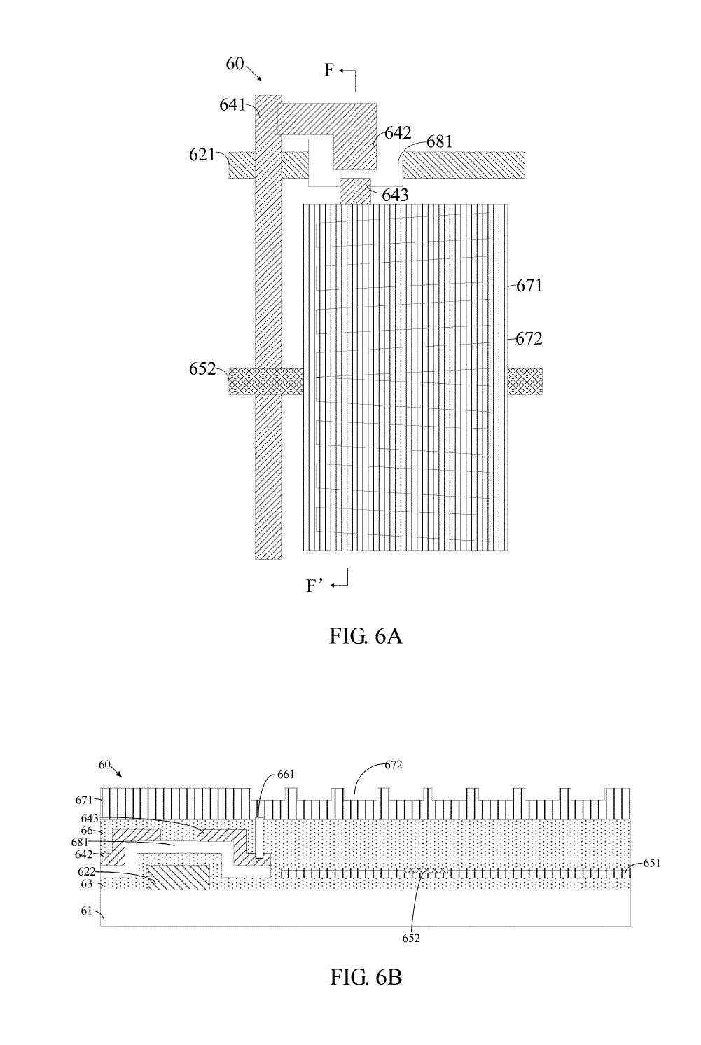

With reference to FIG. 6A and FIG. 6B, an FFS array substrate in accordance with a sixth preferred embodiment will now be described. FIG. 6A is a top view of a schematic diagram of an FFS array substrate in accordance with the sixth preferred embodiment, and FIG. 6B is a cross-sectional view of a schematic diagram along the cross-sectional line F-F′ shown in FIG. 6A. In accordance with the sixth preferred embodiment, the FFS array substrate 60 includes a base substrate 61, a first metal layer, a first insulation layer 63, a second metal layer, a common electrode layer, a second insulation layer 66, and a transparent electrode layer.

The first metal layer disposed on the base substrate 61 is used to form a scan line 621 and a gate electrode of a thin film transistor 622. The first insulation layer 63 disposed on the first metal layer is used for electrically insulating the first metal layer from the second metal layer. The second metal layer disposed on the first insulation layer 63 is used to form a data line 641, a source electrode of the thin film transistor 642, and a drain electrode of the thin film transistor 643. The common electrode layer includes a transparent common electrode 651 disposed on the first insulation layer 63 and a common electrode line 652 disposed on the transparent common electrodes 651, wherein the resistivity of the common electrode line 652 is lower than the resistivity of the transparent common electrodes 651. The second insulation layer 66 disposed on the second metal layer and the common electrode layer is used for electrically insulating the common electrode layer from the transparent electrode layer as well as electrically insulating the second metal layer from the transparent electrode layer. The transparent electrode layer disposed on the second insulation layer 66 is used to form a transparent pixel electrode 671. The transparent pixel electrode 671 is electrically connected with the drain electrode of the thin film transistor 643 by passing through the first through-hole 661 of the second insulation layer 66. Additionally, the FFS array substrate 50 also includes a semiconductor layer used for forming channels 681.

The FFS array substrate 60 contains multiple display domains, and therein a slit structure 672 is arranged on a surface of the transparent pixel electrode 671 and extension directions of slits of the slit structure 672 are distinct for each display domain of the FFS array substrate 60. The common electrode line 652 is arranged on a junction between two adjacent display domains.

The distinction between the fourth preferred embodiment and the sixth preferred embodiment is about the disposition of the common electrode line 652, which is disposed on the transparent common electrodes 651 in the fifth preferred embodiment. The specific operations of the FFS array substrate 60 are similar to the FFS array substrate described in the third embodiment; please refer to the relevant detailed description in the aforementioned preferred embodiments.

The FFS array substrate in accordance with the fifth preferred embodiment can assure stability of the electric potentials of the common electrodes by means of the disposition of the common electrode layer that includes a common electrode line and the transparent common electrodes. Therefore, the display performance of the LCD display device having the FFS array substrate of the present invention is improved.

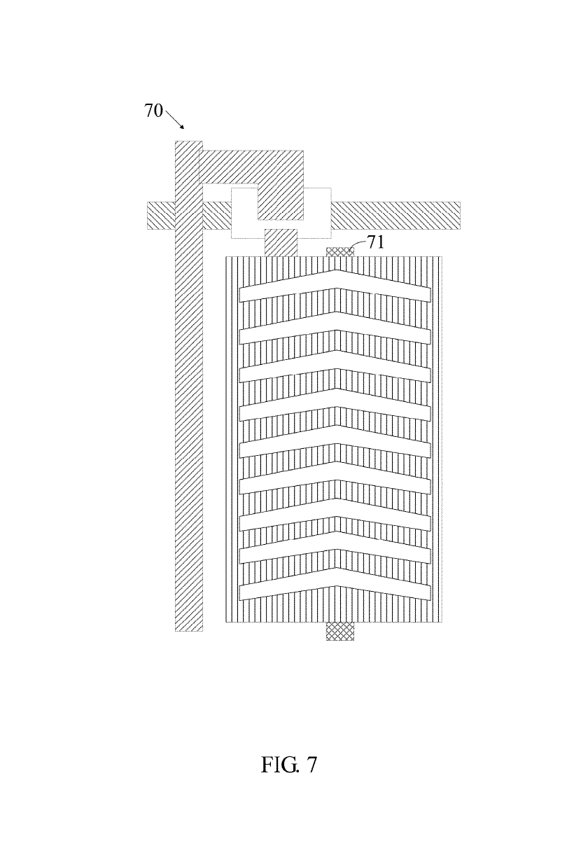

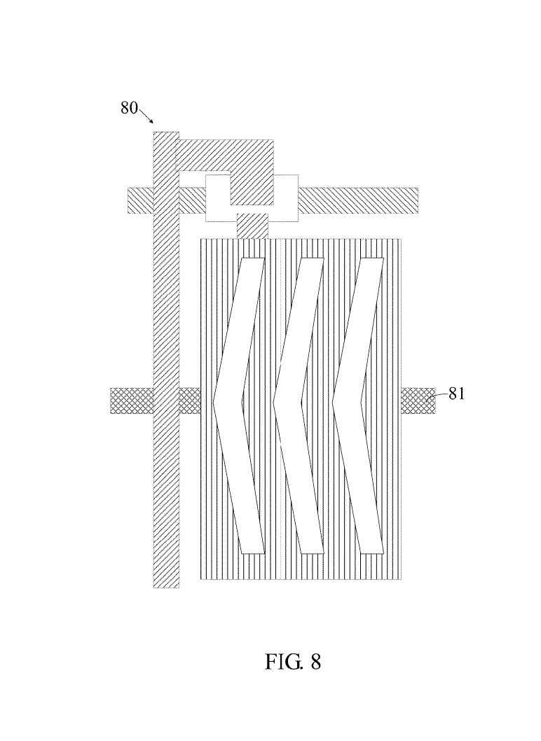

The FFS array substrate of the present invention contains multiple display domains, which are divided depending on clients' demands and physical conditions. Referring to FIG. 7, a top view of a schematic diagram of an FFS array substrate in accordance with a seventh preferred embodiment is shown. There are two display domains representing as a right domain and a left domain for each pixel in the FFS array substrate 700, so the common electrode line 71 is disposed vertically on a center line of each pixel. Referring to FIG. 8, a top view of a schematic diagram of an FFS array substrate in accordance with an eighth preferred embodiment is shown. There are two display domains representing as an upper domain and a bottom domain for each pixel in the FFS array substrate 800, so the common electrode line 81 is disposed horizontally.

Certainly, the arrangement of the common electrode line will be different in light of different divisions for display domains. Merely the common electrode line is arranged on a junction between two adjacent display domains, and it is helpful to achieve reduction of the impedances of the common electrodes and improvement of aperture ratio of the LCD display device under such an arrangement.

The present invention further provides an embodiment of an LCD display panel, which comprises an upper substrate, an FFS array substrate and a liquid crystal layer interposed between the upper substrate and the FFS array substrate. The specific structure and operations of the FFS array substrate are similar or identical to the FFS array substrates in the above described embodiments; please refer to the relevant detailed descriptions of the FFS array substrates in accordance with the above preferred embodiments.

The FFS array substrate and the LCD display panel having the FFS array substrate of the present invention can assure stability of the electric potentials of the common electrodes by means of the disposition of the common electrode layer that includes a common electrode line and the transparent common electrodes. Therefore, the display performance of the LCD display device having the FFS array substrate of the present invention is improved. Simultaneously, the existing technical problem of unstable electric potentials on the common electrodes of the conventional LCD can be solved.

While the present invention has been described in connection with what is considered the most preferred embodiments, it is understood that this invention is not limited to the disclosed embodiments. It will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. An FFS array substrate comprising:
a base substrate;
a first metal layer disposed on the base substrate to form a scan line and a gate electrode of a thin film transistor;
a first insulation layer disposed on the first metal layer to electrically insulate the first metal layer from a second metal layer;
a second metal layer disposed on the first insulation layer to form a data line, a source electrode of the thin film transistor, and a drain electrode of the thin film transistor;
a second insulation layer disposed on the second metal layer to electrically insulate the second metal layer from a common electrode layer;
a common electrode layer including a common electrode line disposed on the second insulation layer and a transparent common electrode disposed on the common electrode line and the second insulation layer, wherein a resistivity of the common electrode line is lower than a resistivity of the transparent common electrode;
a third insulation layer disposed on the common electrode layer to electrically insulate a common electrode layer from a transparent electrode layer; and
a transparent electrode layer disposed on the third insulation layer to form a transparent pixel electrode, which is electrically connected with the drain electrode of the thin film transistor by passing through the third insulation layer, the common electrode layer, and a first through-hole of the second insulation layer.

2. The FFS array substrate according to claim 1, wherein a slit structure is arranged on a surface of the transparent pixel electrode.

3. The FFS array substrate according to claim 2, wherein the FFS array substrate contains multiple display domains.

4. The FFS array substrate according to claim 3, wherein extension directions of slits of the slit structure are distinct for each display domain.

5. The FFS array substrate according to claim 3, wherein the common electrode line is arranged on a junction between two adjacent display domains.

6. The FFS array substrate according to claim 1, wherein the second metal layer includes a common line used for transferring a common signal, and the common electrode layer is electrically connected to the common line of the second metal layer by passing through a second through-hole of the second insulation layer.

7. The FFS array substrate according to claim 1, wherein the common electrode layer includes a transparent common electrode disposed on the second insulation layer and a common electrode line disposed on the transparent common electrode, and wherein a resistivity of the common electrode line is lower than a resistivity of the transparent common electrode.

8. An FFS array substrate comprising:
a base substrate;
a first metal layer disposed on the base substrate to form a scan line and a gate electrode of a thin film transistor;
a first insulation layer disposed on the first metal layer to electrically insulate the first metal layer from a second metal layer as well as electrically insulate the first metal layer from a common electrode layer;
a second metal layer disposed on the first insulation layer to form a data line, a source electrode of the thin film transistor, and a drain electrode of a thin film transistor;
a common electrode layer including a common electrode line disposed on the first insulation layer and a transparent common electrode disposed on the common electrode line and the first insulation layer, wherein a resistivity of the common electrode line is lower than a resistivity of the transparent common electrode;
a second insulation layer disposed on the second metal layer and the common electrode layer to electrically insulate the second metal layer from the transparent electrode layer as well as electrically insulate the common electrode layer from a transparent electrode layer; and
a transparent electrode layer disposed on the second insulation layer to form a transparent pixel electrode, which are electrically connected with the drain electrode of the thin film transistors by passing through a first through-hole of the second insulation layer.

9. The FFS array substrate according to claim 8, wherein a slit structure is arranged on a surface of the transparent pixel electrode.

10. The FFS array substrate according to claim 8, wherein the FFS array substrate contains multiple display domains.

11. The FFS array substrate according to claim 10, wherein extension directions of slits of the slit structure are distinct for each display domain.

12. The FFS array substrate according to claim 10, wherein the common electrode line is arranged on a junction between two adjacent display domains.

13. The FFS array substrate according to claim 8, wherein the first metal layer includes a common line used for transferring common signals, and the common electrode layer is electrically connected to the common line of the first metal layer by passing through a second through-hole of the first insulation layer.

14. An FFS mode liquid crystal transistor display panel including an upper substrate, an FFS array substrate and a liquid crystal layer interposed between the upper substrate and the FFS array substrate, the FFS array substrate comprising:
a base substrate;
a first metal layer disposed on the base substrate to form a scan line and a gate electrode of a thin film transistor;
a first insulation layer disposed on the first metal layer to electrically insulate the first metal layer from a second metal layer;
a second metal layer disposed on the first insulation layer to form a data line, a source electrode of the thin film transistor, and a drain electrode of the thin film transistor;
a second insulation layer disposed on the second metal layer to electrically insulate the second metal layer from a common electrode layer;
a common electrode layer including a common electrode line disposed on the second insulation layer and a transparent common electrode disposed on the common electrode line and the second insulation layer, wherein a resistivity of the common electrode line is lower than a resistivity of the transparent common electrode;
a third insulation layer disposed on the common electrode layer to electrically insulate a common electrode layer from a transparent electrode layer; and
a transparent electrode layer disposed on the third insulation layer to form a transparent pixel electrode, which is electrically connected with the drain electrode of thin film transistor by passing through the third insulation layer, the common electrode layer, and a first through-hole of the second insulation layer.

15. The FFS array substrate according to claim 14, wherein a slit structure is arranged on a surface of the transparent pixel electrode.

16. The FFS array substrate according to claim 15, wherein the FFS array substrate contains multiple display domains.

17. The FFS array substrate according to claim 16, wherein extension directions of slits of the slit structure are distinct for each display domain.

18. The FFS array substrate according to claim 16, wherein the common electrode line is arranged on a junction between two adjacent display domains.

19. The FFS array substrate according to claim 14, wherein the second metal layer includes a common line used for transferring a common signal, and the common electrode layer is electrically connected to the common line by passing through a second through-hole of the second insulation layer.

20. The FFS array substrate according to claim 14, wherein the common electrode layer includes a transparent common electrode disposed on the second insulation layer and a common electrode line disposed on the transparent common electrode, and wherein a resistivity of the common electrode line is lower than a resistivity of the transparent common electrode.
